(19) United States
(12) Patent Application Publication
(10) Pub. No.: US 2025/0048873 A1
(43) Pub. Date: Feb. 6, 2025

(54) DISPLAY DEVICE AND OPTICAL DEVICE

(71) Applicant: Samsung Display Co., Ltd., Yongin-Si (KR)

(72) Inventors: Jung Hyun SON, Yongin-si (KR); Rae Young KIM, Yongin-si (KR); Jong Min OK, Yongin-si (KR); Sang Yeol KIM, Yongin-si (KR); Sung Soo LEE, Yongin-si (KR)

(21) Appl. No.: 18/668,270

(22) Filed: May 20, 2024

(30) Foreign Application Priority Data
Aug. 1, 2023 (KR) 10-2023-0100462

(51) Int. Cl. H10K 59/38; G02B 27/01; H10K 59/123; H10K 59/80

(52) U.S. Cl. CPC H10K 59/38; G02B 27/0172; H10K 59/123; H10K 59/873; H10K 59/879; G02B 2027/0178

(57) ABSTRACT

The present disclosure relates to a display device, and more particularly, to a display device capable of improving color gamut and minimizing a thickness of a filling layer, and an optical device including the same. The display device includes a substrate; a transistor disposed on the substrate; a pixel electrode connected to the transistor; a light emitting layer disposed on the pixel electrode; a common electrode disposed on the light emitting layer; a color filter disposed on the common electrode; a lens disposed on the color filer; and a filling layer disposed on the lens, wherein the color filter and the lens are in direct contact with each other.

### CROSS-REFERENCE TO RELATED APPLICATION

This application claims priority to Korean Patent Application No. 10-2023-0100462 filed on Aug. 1, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, and more particularly, to a display device capable of improving color gamut and minimizing a thickness of a filling layer, and an optical device including the same.

### 2. Description of the Related Art

A head mounted display (HMD) is an image display device that is worn on a user's head in the form of glasses or a helmet and focuses on a distance close to the user's eyes. The head mounted display may realize virtual reality (VR) or augmented reality (AR).

The head mounted display enlarges and displays an image displayed on a small display device using a plurality of lenses. Therefore, a display device applied to the head mounted display needs to provide a high-resolution image, for example, an image having a resolution of 3000 pixels per inch (PPI) or higher. To this end, organic light emitting diode on silicon (OLEDoS), which can implement a high-resolution and small-sized organic light emitting display device, is used as the display device applied to the head mounted display. The OLEDOS is a device that displays an image by disposing an organic light emitting diode (OLED) on a semiconductor wafer substrate on which a complementary metal oxide semiconductor (CMOS) is disposed.

### SUMMARY

Aspects of the present disclosure provide a display device and an optical device capable of improving color gamut and minimizing a thickness of a filling layer.

According to an embodiment of the disclosure, a display device comprising: a substrate; a transistor disposed on the substrate; a pixel electrode connected to the transistor;

a light emitting layer disposed on the pixel electrode; a common electrode disposed on the light emitting layer; a first color filter disposed on the common electrode; a lens disposed on the color filer; and a filling layer on the lens, wherein the first color filter and the lens are in direct contact with each other.

In an embodiment, a difference between a refractive index of the lens and a refractive index of the filling layer is 0.1 to 0.2

In an embodiment, a refractive index of the lens is greater than a refractive index of the filling layer.

In an embodiment, the lens has a refractive index of 1.61.

In an embodiment, the lens has a taper angle of 60 degrees to 70 degrees.

In an embodiment, the lens has a thickness smaller than 1.5 μm.

In an embodiment, wherein a distance between adjacent lenses is greater than or equal to 0.3 μm.

In an embodiment, the filling layer has a refractive index of 1.41 to 1.51.

In an embodiment, the filling layer includes an epoxy.

In an embodiment, the filling layer has a thickness of 3 μm.

In an embodiment, further comprising a second buffer layer disposed between the lens and the filling layer.

In an embodiment, the second buffer layer has a refractive index of 1.4 to 1.7.

In an embodiment, the second buffer layer has a thickness smaller than 1000 Å.

In an embodiment, the second buffer layer has a surface energy greater than or equal to 60 mN/m.

In an embodiment, the second buffer layer includes SiOxNy.

In an embodiment, further comprising an encapsulating layer disposed between the common electrode and the first color filter.

In an embodiment, the encapsulation layer includes at least one inorganic film and at least one organic film disposed on different layers.

In an embodiment, the encapsulation layer further includes a first buffer layer disposed between the inorganic film and the organic film of the encapsulation layer.

In an embodiment, the first buffer layer has a refractive index of 1.4 to 1.7.

In an embodiment, further comprising a second color filter disposed adjacent to the first color filter and overlapping the first color filter in a plan view.

In an embodiment, a thickness of an overlapping portion of the first color filter and the second color filter is equal to a thickness of the lens.

In an embodiment, a width of an overlapping portion of the first color filter and the second color filter is less than or equal to 0.2 μm.

According to an embodiment of the disclosure, a display device comprising: a substrate; a transistor disposed on the substrate; a pixel electrode connected to the transistor; a light emitting layer disposed on the pixel electrode; a common electrode disposed on the light emitting layer; a color filter disposed on the common electrode; a lens disposed on the color filer; and a filling layer disposed on the lens, wherein the filling layer has a refractive index of 1.41 to 1.51.

In an embodiment, a difference between a refractive index of the lens and the refractive index of the filling layer is 0.1 to 0.2.

In an embodiment, a refractive index of the lens is greater than the refractive index of the filling layer.

In an embodiment, the lens has a refractive index of 1.61.

In an embodiment, the lens has a taper angle of 60 degrees to 70 degrees.

In an embodiment, the color filter and the lens are in direct contact with each other.

According to an embodiment of the disclosure, an optical device comprising: a display device; and an optical path conversion member on the display device, wherein the display device includes: a substrate; a transistor disposed on the substrate; a pixel electrode connected to the transistor; a light emitting layer disposed on the pixel electrode; a common electrode disposed on the light emitting layer; a color filter disposed on the common electrode; a lens disposed on the color filer; and a filling layer disposed on the lens, and the color filter and the lens are in direct contact with each other.

According to the display device of the present disclosure, the color gamut may be improved and the thickness of the filling layer may be minimized.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view illustrating a display device according to an exemplary embodiment;

FIG. 2 is a layout view illustrating an example of a display panel illustrated in FIG. 1;

FIG. 3 is a block diagram illustrating the display device according to an exemplary embodiment;

FIG. 4 is an equivalent circuit diagram of a first pixel according to an exemplary embodiment;

FIG. 5 is a layout view illustrating pixels of a display area according to an exemplary embodiment;

FIG. 6 is a cross-sectional view illustrating an example of the display device taken along line A-A′ of FIG. 5;

FIG. 7 is a perspective view illustrating a head mounted display device according to an exemplary embodiment;

FIG. 8 is an exploded perspective view illustrating an example of a display unit 1700 of the head mounted display device of FIG. 7;

FIG. 9 is a perspective view illustrating a head mounted display device according to an exemplary embodiment;

FIG. 10 is a plan view of a display device according to an exemplary embodiment;

FIG. 11 is a cross-sectional view of the display device according to an exemplary embodiment taken along line I-I′ of FIG. 10;

FIG. 12 is a cross-sectional view of the display device according to an exemplary embodiment taken along line I-I′ of FIG. 10;

FIG. 13 is a cross-sectional view of the display device according to an exemplary embodiment taken along line I-I′ of FIG. 10;

FIG. 14 is a view for describing front light efficiency of a display device according to a refractive index of a filling layer and a taper angle of a lens;

FIG. 15 is a view for describing side light efficiency (or side luminance ratio) of a display device according to a refractive index of a filling layer and a taper angle of a lens;

FIG. 16 is a view for describing a front color difference of a display device according to a refractive index of a filling layer and a taper angle of a lens; and

FIG. 17 is a view for describing a side color difference of a display device according to a refractive index of a filling layer and a taper angle of a lens.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific exemplary embodiments will be described with reference to the accompanying drawings.

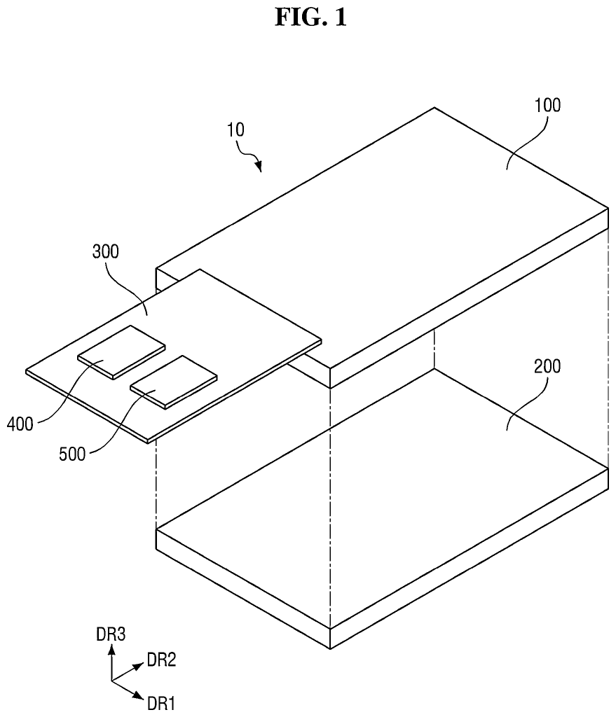

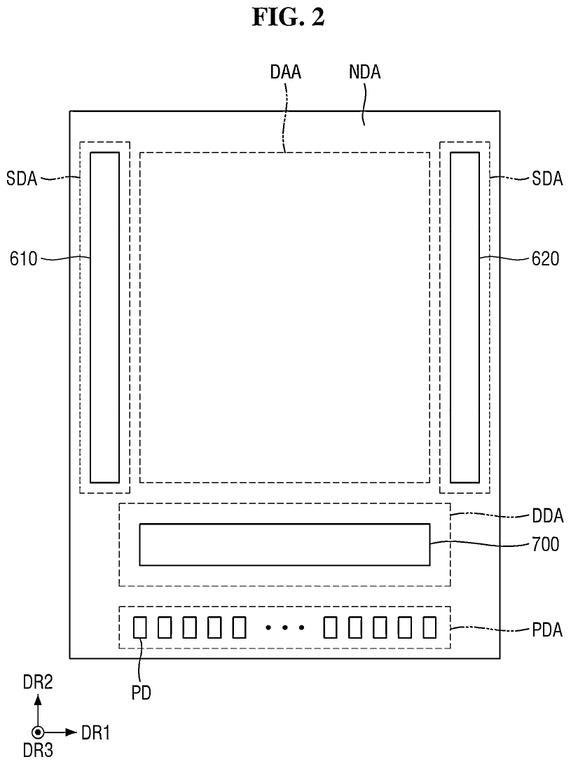

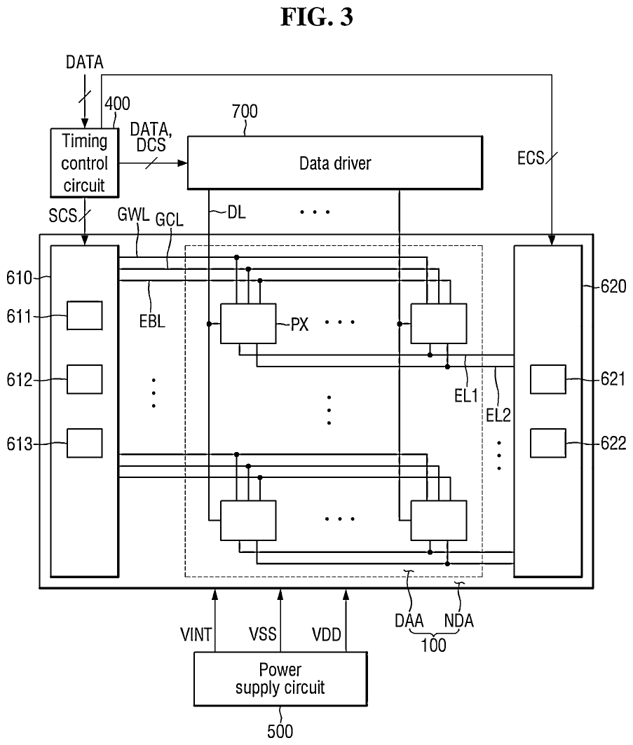

FIG. 1 is an exploded perspective view illustrating a display device according to an exemplary embodiment. FIG. 2 is a layout view illustrating an example of a display panel illustrated in FIG. 1. FIG. 3 is a block diagram illustrating the display device according to an exemplary embodiment.

Referring to FIGS. 1 and 2, a display device 10 according to an exemplary embodiment is a device displaying a moving image or a still image. The display device 10 according to an exemplary embodiment may be applied to portable electronic devices such as a mobile phone, a smart phone, a tablet personal computer (PC), a mobile communication terminal, an electronic notebook, an electronic book, a portable multimedia player (PMP), navigation, and an ultra-mobile PC (UMPC). For example, the display device 10 may be applied to a display unit of a television, a laptop computer, a monitor, a billboard, or the Internet of Things (IOT). Alternatively, the display device 10 may be applied to a smart watch, a watch phone, and a head mounted display (HMD) for implementing virtual reality and augmented reality.

The display device 10 according to an exemplary embodiment includes a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side extending in the first direction DR1 and the long side extending in the second direction DR2 meet may be rounded to have a predetermined curvature or may be formed at a right angle. The planar shape of the display panel 100 is not limited to the quadrangle, and may be formed to have other polygons, circles, or ovals. A planar shape of the display device 10 may follow the planar shape of the display panel 100, but the exemplary embodiment of the present specification is not limited thereto.

As illustrated in FIG. 2, the display panel 100 includes a display area DAA displaying an image and a non-display area NDA that does not display an image.

The display area DAA includes a plurality of pixels PX, a plurality of scan lines SL, a plurality of emission control lines EL, and a plurality of data lines DL.

Each of the plurality of pixels PX includes a light emitting element emitting light. The plurality of pixels PX may be arranged in a matrix form in the first direction DR1 and the second direction DR2. The plurality of scan lines SL and the plurality of emission control lines EL may extend in the first direction DR1 and may be disposed in the second direction DR2. The plurality of data lines DL may extend in the second direction DR2 and may be disposed in the first direction DR1.

The plurality of scan lines SL includes a plurality of write scan lines GWL, a plurality of control scan lines GCL, and a plurality of bias scan lines EBL. The plurality of emission control lines EL include a plurality of first emission control lines EL1 and a plurality of second emission control lines EL2.

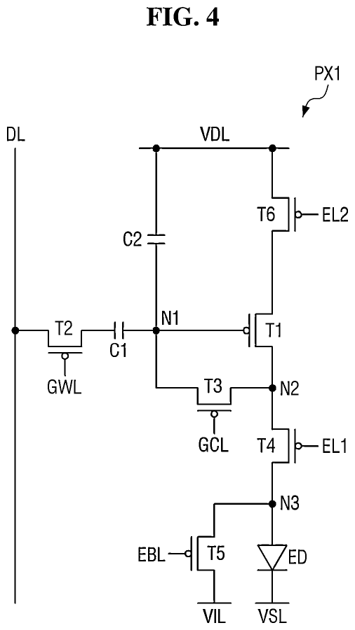

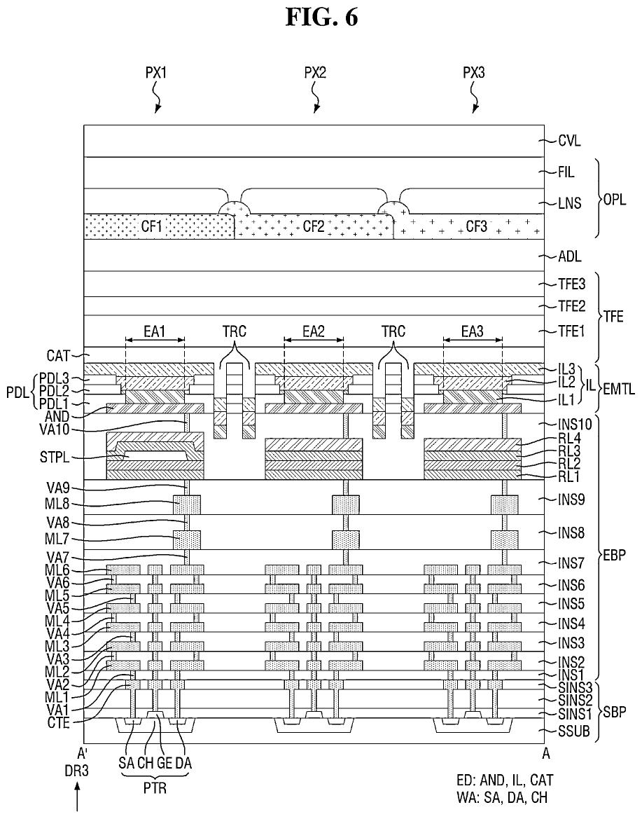

A plurality of unit pixels UPX include a plurality of pixels PX1, PX2, and PX3. Each of the plurality of pixels PX1, PX2, and PX3 may include a plurality of pixel transistors as illustrated in FIG. 4, and the plurality of pixel transistors may be formed through a semiconductor process and may be disposed on a semiconductor substrate (SSUB in FIG. 6). For example, the plurality of pixel transistors may be formed of a complementary metal oxide semiconductor (CMOS).

Each of the plurality of pixels PX1, PX2, and PX3 may be connected to any one write scan line GWL among the plurality of write scan lines GWL, any one control scan line GCL among the plurality of control scan lines GCL, any one bias scan line EBL among the plurality of bias scan lines EBL, any one first emission control line EL1 among the plurality of first emission control lines EL1, any one second emission control line EL2 among the plurality of second emission control lines EL2, and any one data line DL among the plurality of data lines DL. Each of the plurality of pixels PX1, PX2, and PX3 may receive a data voltage supplied from the data line DL in response to a write scan signal of the write scan line GWL, and may emit light from the light emitting element according to the data voltage.

The non-display area NDA includes a scan driving area SDA, a data driving area DDA, and a pad area PDA.

The scan driving area SDA may be an area in which a scan driver 610 and an emission driver 620 are disposed. It is illustrated in FIG. 2 that the scan driver 610 is disposed on the left side of the display area DAA, and the emission driver 620 is disposed on the right side of the display area DAA, but the exemplary embodiment of the present specification is not limited thereto. For example, the scan driver 610 and the emission driver 620 may be disposed on both the left and right sides of the display area DAA.

The scan driver 610 includes a plurality of scan transistors, and the emission driver 620 includes a plurality of light emitting transistors. The plurality of scan transistors and the plurality of light emitting transistors may be formed through a semiconductor process and may be formed on a semiconductor substrate (SSUB in FIG. 6). For example, the plurality of scan transistors and the plurality of light emitting transistors may be formed of CMOS.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driving area DDA may be an area in which a data driver 700 is disposed. The data driver 700 may include a plurality of data transistors, and the plurality of data transistors may be formed through a semiconductor process and may be formed on a semiconductor substrate (SSUB in FIG. 6). For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the pixels PX1, PX2, and PX3 may be selected by the write scan signal of the scan driver 610, and the data voltages may be supplied to the selected pixels PX1, PX2, and PX3.

The pad area PDA includes a plurality of pads PD disposed in the first direction DR1. Each of the plurality of pads PD may be exposed by removing insulating layers disposed on it, for example, a cover layer (CVL in FIG. 6) and a polarizing plate (not illustrated).

The heat dissipation layer 200 may overlap the display panel 100 in a third direction DR3, which is a thickness direction of the display panel 100. The heat dissipation layer 200 may be disposed on one surface, for example, a rear surface of the display panel 100. The heat dissipation layer 200 serves to dissipate heat generated from the display panel 100. The heat dissipation layer 130 may include a metal layer such as graphite, silver (Ag), copper (Cu), or aluminum (Al) having high thermal conductivity.

The circuit board 300 may be electrically connected to the plurality of pads PD in the pad area PDA of the display panel 100 by using a conductive adhesive member such as an anisotropic conductive film. The circuit board 300 may be a flexible printed circuit board having a flexible material or a flexible film. It is illustrated in FIG. 1 that the circuit board 300 is unfolded, but the circuit board 300 may be bent. In this case, one end of the circuit board 300 may be disposed on the rear surface of the display panel 100. One end of the circuit board 300 may be an opposite end of the circuit board 300 connected to the plurality of pads PD in the pad area PDA.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

The power supply circuit 500 may generate a plurality of panel driving voltages by converting an external power voltage. For example, the power supply circuit 500 may generate and supply a first driving voltage VSS, a second driving voltage VDD, and a third driving voltage VINT to the display panel 100. A description of the first driving voltage VSS, the second driving voltage VDD, and the third driving voltage VINT will be described later with reference to FIG. 4.

Each of the timing control circuit 400 and the power supply circuit 500 may be formed as an integrated circuit (IC) and attached to one surface of the circuit board 300. The scan timing control signal SCS, the emission timing control signal ECS, the digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

FIG. 4 is an equivalent circuit diagram of a first pixel according to an exemplary embodiment.

Referring to FIG. 4, the first pixel PX1 may be connected to the write scan line GWL, the control scan line GCL, the bias scan line EBL, the first emission control line EL1, the second emission control line EL2, and the data line DL. In addition, the first pixel PX1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The first pixel PX1 includes a plurality of transistors T1 to T6, a light emitting element LE, a first capacitor C1, and a second capacitor C2.

The light emitting element ED emits light according to a driving current Ids flowing through a channel of a first transistor T1. An amount of light emitted from the light emitting element ED may be proportional to the driving current Ids. The light emitting element ED may be disposed between a fourth transistor T4 and the first driving voltage line VSL. A first electrode of the light emitting element ED may be connected to a drain electrode of the fourth transistor T4, and a second electrode thereof may be connected to the first driving voltage line VSL. The first electrode of the light emitting element ED may be an anode electrode, and the second electrode of the light emitting element ED may be a cathode electrode. The light emitting element ED may be an organic light emitting diode including a first electrode, a second electrode, and an organic light emitting layer disposed between the first electrode and the second electrode, but the exemplary embodiment of the present specification is not limited thereto. For example, the light emitting element ED may be an inorganic light emitting device including a first electrode, a second electrode, and an inorganic semiconductor disposed between the first electrode and the second electrode. In this case, the light emitting element ED may be a micro light emitting diode.

The first transistor T1 may be a driving transistor that controls a source-drain current (Ids, hereinafter, referred to as “driving current”) flowing between a source electrode and a drain electrode according to a voltage applied to a gate electrode. The first transistor T1 includes a gate electrode connected to a first node N1, a source electrode connected to a drain electrode of a sixth transistor T6, and a drain electrode connected to a second node N2.

The second transistor T2 may be connected between one electrode of the first capacitor C1 and the data line DL. The second transistor T2 is turned on in response to the write scan signal of the write scan line GWL and connects one electrode of the first capacitor C1 to the data line DL. Accordingly, the data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be connected between the first node N1 and the second node N2. The third transistor T3 is turned on in response to the write control signal of the write control line GCL and connects the first node N1 to the second node N2. Accordingly, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element ED. The fourth transistor T4 includes a gate electrode connected to the first emission control line EL1, a source electrode connected to the second node N2, and a drain electrode connected to the third node N3.

The fifth transistor T5 may be connected between the third node N3 and the third driving voltage line VIL. The fifth transistor T5 is turned on by the bias scan signal of the bias scan line EBL and connects the third node N3 to the third driving voltage line VIL. Accordingly, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

The sixth transistor T6 may be connected between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is connected between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor C1, and one electrode of the second capacitor C2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element ED.

Each of the first to sixth transistors T1 to T6 may be a metal-oxide-semiconductor field effect transistor (MOSFET). For example, each of the first to sixth transistors T1 to T6 may be a P-type MOSFET, but the exemplary embodiment of the present specification is not limited thereto. Each of the first to sixth transistors T1 to T6 may be an N-type MOSFET. Alternatively, some of the first to sixth transistors T1 to T6 may be a P-type MOSFET, and others of the first to sixth transistors T1 to T6 may be an N-type MOSFET.

It is illustrated in FIG. 4 that the first pixel PX1 includes six transistors T1 to T6 and two capacitors C1 and C2, but it should be noted that the equivalent circuit diagram of the first pixel PX1 is not limited to that illustrated in FIG. 4. For example, the number of transistors and capacitors of the first pixel PX1 is not limited to that illustrated in FIG. 4.

In addition, an equivalent circuit diagram of the second pixel PX2 and an equivalent circuit diagram of the third pixel PX3 may be substantially the same as the equivalent circuit diagram of the first pixel PX1 described with reference to FIG. 4. Therefore, descriptions of the equivalent circuit diagram of the second pixel PX2 and the equivalent circuit diagram of the third pixel PX3 are omitted in the present specification.

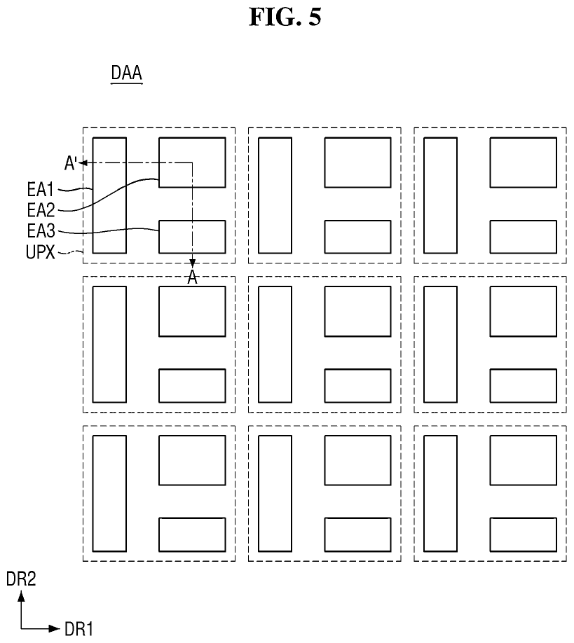

FIG. 5 is a layout view illustrating pixels of a display area according to an exemplary embodiment.

Referring to FIG. 5, each of the plurality of pixels PX includes a first light emitting area EA1 which is a light emitting area of the first pixel PX1, a second light emitting area EA2 which is a light emitting area of the second pixel PX2, and a third light emitting area EA which is a light emitting area of the third pixel PX3.

Each of the first light emitting area EA1, the second light emitting area EA2, and the third light emitting area EA3 may have a quadrangular planar shape such as a rectangle, a square, or a rhombus. For example, the first light emitting area EA1 may have a rectangular planar shape having a short side in the first direction DR1 and a long side in the second direction DR2. In addition, each of the second light emitting area EA2 and the third light emitting area EA3 may have a rectangular planar shape having a long side in the first direction DR1 and a short side in the second direction DR2.

A length of the first light emitting area EA1 in the first direction DR1 may be smaller than a length of the second light emitting area EA2 in the first direction DR1, and may be smaller than a length of the third light emitting area EA3 in the first direction DR1. The length of the second light emitting area EA2 in the first direction DR1 and the length of the third light emitting area EA3 in the first direction DR1 may be substantially the same.

A length of the first light emitting area EA1 in the second direction DR2 may be greater than a sum of a length of the second light emitting area EA2 in the second direction DR2 and a length of the third light emitting area EA3 in the second direction DR2. The length of the second light emitting area EA2 in the second direction DR2 may be shorter than the length of the third light emitting area EA3 in the second direction DR2.

It is illustrated in FIG. 5 that each of the first light emitting area EA1, the second light emitting area EA2, and the third light emitting area EA3 has a quadrangular planar shape, but the exemplary embodiment of the present specification is not limited thereto. For example, each of the first light emitting area EA1, the second light emitting area EA2, and the third light emitting area EA3 may have a polygonal, circular, or elliptical planar shape other than the quadrangular shape.

In each of the plurality of pixels PX, the first light emitting area EA1 and the second light emitting area EA2 may be disposed adjacent to each other in the first direction DR1. In addition, the first light emitting area EA1 and the third light emitting area EA3 may be disposed adjacent to each other in the first direction DR1. In addition, the second light emitting area EA2 and the third light emitting area EA3 may be disposed adjacent to each other in the second direction DR2. An area of the first light emitting area EA1, an area of the second light emitting area EA2, and an area of the third light emitting area EA3 may be different.

The first light emitting area EA1 emits light of a first color, the second light emitting area EA2 emits light of a second color, and the third light emitting area EA3 emits light of a third color. Here, the light of the first color may be light in a blue wavelength band, the light of the second color may be light in a green wavelength band, and the light of the third color may be light in a red wavelength band. For example, the blue wavelength band may indicate that a main peak wavelength of light is included in a wavelength band of approximately 370 nm to 460 nm, the green wavelength band may indicate that a main peak wavelength of light is included in a wavelength band of approximately 480 nm to 560 nm, and the red wavelength band may indicate that a main peak wavelength of light is included in a wavelength band of approximately 600 nm to 750 nm.

It is illustrated in FIG. 5 that each of the plurality of pixels PX includes three light emitting areas EA1, EA2, and EA3, but the exemplary embodiment of the present specification is not limited thereto. That is, each of the plurality of pixels PX may also include four light emitting areas.

In addition, the arrangement of the light emitting areas of the plurality of pixels PX is not limited to that illustrated in FIG. 5. For example, the light emitting areas of the plurality of pixels PX may be disposed in a stripe structure in which the light emitting areas are arranged in the first direction DR1, a PenTile® structure in which the light emitting areas have a diamond arrangement, or a hexagonal structure in which light emitting areas having a hexagonal planar shape are arranged.

FIG. 6 is a cross-sectional view illustrating an example of the display device taken along line A-A′ of FIG. 5.

Referring to FIG. 6, the display panel 100 includes a semiconductor backplane SBP, a light emitting element backplane EBP, a light emitting element layer EMTL, an encapsulation layer TFE, an optical layer OPL, a cover layer CVL, and a polarizing plate (not shown).

The semiconductor backplane SBP includes a semiconductor substrate SSUB including a plurality of source areas and a plurality of drain areas of a plurality of pixel transistors PTR are disposed, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with first-type impurities. A plurality of wells WA may be disposed in the semiconductor substrate SSUB. The plurality of wells WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of wells WA includes a source area SA corresponding to a source electrode of the pixel transistor PTR, a drain area DA corresponding to a drain electrode thereof, and a channel area CH disposed between the source area SA and the drain area DA.

Each of the source area SA and the drain area DA may be an area heavily doped with first-type impurities. A gate electrode GE of the pixel transistor PTR may overlap the well WA in the third direction DR3. The channel area CH may overlap the gate electrode GE in the third direction DR3. The source area SA may be disposed on one side of the gate electrode GE, and the drain area DA may be disposed on the other side of the gate electrode GE.

Each of the plurality of wells WA further includes a first lightly doped area LDD1 disposed between the channel area CH and the source area SA and a second lightly doped area LDD2 disposed between the channel area CH and the drain area DA. The first lightly doped area LDD1 may be an area having an impurity concentration lower than that of the source area SA. The second lightly doped area LDD2 may be an area having an impurity concentration lower than that of the drain area DA. A distance between the source area SA and the drain area DA may be increased by the first lightly doped area LDD1 and the second lightly doped area LDD2. Therefore, since a length of the channel area CH of each of the pixel transistors PTR may increase, punch-through and hot carrier phenomena caused by a short channel may be prevented.

A gate insulating layer (not shown) may be disposed between the semiconductor substrate SSUB and the gate electrode GE. A first semiconductor insulating film SINS1 may be disposed on the semiconductor substrate SSUB. The first semiconductor insulating film SINS1 may be formed as a silicon nitride (SiCN) or silicon oxide (SiOx)-based inorganic film, but the exemplary embodiment of the present specification is not limited thereto.

A semiconductor insulating film SINS2 may be disposed on the first semiconductor insulating film SINS1. The second semiconductor insulating film SINS2 may include a silicon oxide (SiOx)-based inorganic film, but the exemplary embodiment of the present specification is not limited thereto.

A plurality of contact terminals CTE may be disposed on the second semiconductor insulating film SINS2. Each of the plurality of contact terminals CTE may be connected to any one of the gate electrode GE, the source area SA, and the drain area DA of each of the plurality of pixel transistors PTR through a contact hole formed through the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be disposed on the plurality of contact terminals CTE. An upper surface of each of the plurality of contact terminals CTE may be exposed by a contact hole formed through the third semiconductor insulating film SINS3. The third semiconductor insulating film SINS3 may be formed as a silicon oxide (SiOx)-based inorganic film, but the exemplary embodiment of the present specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes first to eighth metal layers ML1 to ML8, reflective metal layers RL1 to RL4, a plurality of vias VA1 to VA10, and a stepped layer STPL. In addition, the light emitting element backplane EBP includes a plurality of interlayer insulating films INS1 to INS10 disposed between the first to sixth metal layers ML1 to ML8.

The first to eighth metal layers ML1 to ML8 serve to implement the circuit of the first pixel PX1 illustrated in FIG. 4 by connecting the plurality of contact terminals CTE exposed from the semiconductor backplane SBP. That is, only the first to sixth transistors T1 to T6 are formed on the semiconductor backplane SBP, and the first to sixth transistors T1 to T6 and the first and second capacitors C1 and C2 are connected through the first to eighth metal layers ML1 to ML8. In addition, the drain area corresponding to the drain electrode of the fourth transistor T4, the source area corresponding to the source electrode of the fifth transistor T5, and the first electrode of the light emitting element ED are also connected through the first to eighth metal layers ML1 to ML8.

A first interlayer insulating film INS1 may be disposed on the semiconductor backplane SBP. Each of the first vias VA1 may formed through the first interlayer insulating film INS1 and be connected to the contact terminal CTE exposed from the semiconductor backplane SBP. Each of the first metal layers ML1 may be disposed on the first interlayer insulating film INS1 and may be connected to the first via VA1.

A second interlayer insulating film INS2 may be disposed on the first interlayer insulating film INS1 and the first metal layers ML1. Each of the second vias VA2 may be connected to the first metal layer ML1 via a contact hole formed through the second interlayer insulating film INS2. Each of the second metal layers ML2 may be disposed on the second interlayer insulating film INS2 and may be connected to the second via VA2.

A third interlayer insulating film INS3 may be disposed on the second interlayer insulating film INS2 and the second metal layers ML2. Each of the third vias VA3 may be connected to the second metal layer ML2 via a contact hole formed through the third interlayer insulating film INS3. Each of the third metal layers ML3 may be disposed on the third interlayer insulating film INS3 and may be connected to the third via VA3.

A fourth interlayer insulating film INS4 may be disposed on the third interlayer insulating film INS3 and the third metal layers ML3. Each of the fourth vias VA4 may be connected to the third metal layer ML3 via a contact hole formed through the fourth interlayer insulating film INS4. Each of the fourth metal layers ML4 may be disposed on the fourth interlayer insulating film INS4 and may be connected to the fourth via VA4.

A fifth interlayer insulating film INS5 may be disposed on the fourth interlayer insulating film INS4 and the fourth metal layers ML4. Each of the fifth vias VA5 may be connected to the fourth metal layer ML4 via a contact hoe formed through the fifth interlayer insulating film INS5. Each of the fifth metal layers ML5 may be disposed on the fifth interlayer insulating film INS5 and may be connected to the fifth via VA5.

A sixth interlayer insulating film INS6 may be disposed on the fifth interlayer insulating film INS5 and the fifth metal layers ML5. Each of the sixth vias VA6 may be connected to the fifth metal layer ML5 a contact hole formed through the sixth interlayer insulating film INS6. Each of the sixth metal layers ML6 may be disposed on the sixth interlayer insulating film INS6 and may be connected to the sixth via VA6.

A seventh interlayer insulating film INS7 may be disposed on the sixth interlayer insulating film INS6 and the sixth metal layers ML6. Each of the seventh vias VA7 may be connected to the sixth metal layer ML6 via a contact hole formed through the seventh interlayer insulating film INS7. Each of the seventh metal layers ML7 may be disposed on the seventh interlayer insulating film INS7 and may be connected to the seventh via VA7.

An eighth interlayer insulating film INS8 may be disposed on the seventh interlayer insulating film INS7 and the seventh metal layers ML7. Each of the eighth vias VA8 may be connected to the seventh metal layer ML7 via a contact hole formed through the eighth interlayer insulating film INS8. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially the same material. The first to eighth interlayer insulating films INS1 to INS8 may be formed as a silicon oxide (SiOx)-based inorganic film, but the exemplary embodiment of the present specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same. For example, the thickness of the first metal layer ML1 may be approximately 1360 Å, each of the thickness of the second metal layer ML2, the thickness of the third metal layer ML3, the thickness of the fourth metal layer ML4, the thickness of the fifth metal layer ML5, and the thickness of the sixth metal layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be 1150 Å.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same. For example, each of the thickness of the seventh metal layer ML7 and the thickness of the eighth metal layer ML8 may be approximately 9000 Å. Each of the thicknesses of the seventh via VA7 and the eighth via VA8 may be approximately 6000 Å.

A ninth interlayer insulating film INS9 may be disposed on the eighth interlayer insulating film INS8 and the eighth metal layers ML8. The ninth interlayer insulating film INS9 may be formed as a silicon oxide (SiOx)-based inorganic film, but the exemplary embodiment of the present specification is not limited thereto.

Each of the ninth vias VA9 may be connected to the eighth metal layer ML8 via a contact hole formed through the ninth interlayer insulating film INS9. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. A thickness of the ninth via VA9 may be approximately 16500 Å.

Each of first reflective electrodes RL1 may be disposed on the ninth interlayer insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the second reflective electrodes RL2 may be formed of titanium nitride (TiN).

In the first pixel PX1, a stepped layer STPL may be disposed on the second reflective electrode RL2. The stepped layer STPL may not be disposed in each of the second pixel PX2 and the third pixel PX3. A thickness of the stepped layer STPL may be set in consideration of a wavelength of light of a first color and a distance from an intermediate layer IL to a fourth reflective electrode RL4 to be advantageous in reflecting the light of the first color emitted from the intermediate layer IL of the first pixel PX1. The stepped layer STPL may be formed of a silicon carbon nitride (SiCN) or silicon oxide (SiOx)-based inorganic film, but the embodiments of the present specification are not limited thereto. The thickness of the stepped layer STPL may be approximately 400 Å.

In the first pixel PX1, a third reflective electrode RL3 may be disposed on the second reflective electrode RL2 and the stepped layer STPL. In the second and third pixels PX2 and PX3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrodes RL4 may be layers that reflect light from first to third intermediate layer IL. The fourth reflective electrodes RL4 may include a metal having a high reflectance to efficiently reflecting light from the intermediate layer IL. The fourth reflective electrode RL4 may be formed of aluminum (Al), a stacked structure (Ti/Al/Ti) of aluminum and titanium, a stacked structure (ITO/AI/ITO) of aluminum and ITO, an APC alloy, which is an alloy of silver (Ag), palladium (Pd), and copper (Cu), and a stacked structure (ITO/APC/ITO) of an APC alloy and ITO, but the exemplary embodiment of the present specification is not limited thereto. A thickness of each of the fourth reflective electrodes RL4 may be approximately 850 Å.

A tenth interlayer insulating film INS10 may be disposed on the ninth interlayer insulating film INS9 and the fourth reflective electrode RL4. The tenth interlayer insulating film INS10 may be formed as a silicon oxide (SiOx)-based inorganic film, but the exemplary embodiment of the present specification is not limited thereto.

Each of the tenth vias VA10 may be connected to the ninth metal layer ML9 via a contact hole formed through the tenth interlayer insulating film INS10. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. Due to the stepped layer STPL, a thickness of the tenth via VA10 in the first pixel PX1 may be smaller than a thickness of the tenth via VA10 in each of the second and third pixels PX2 and PX3. For example, the thickness of the tenth via VA10 in the first pixel PX1 may be approximately 800 Å, and the thickness of the tenth via VA10 in each of the second and third pixels PX2 and PX3 may be approximately 1200 Å.

The light emitting element layer EMTL may be disposed on the light emitting element backplane EBP. The light emitting element layer EMTL may include light emitting elements ED each including a first electrode AND, an intermediate layer IL, and a second electrode CAT, a pixel defining film PDL, and a plurality of trenches TRC.

The first electrode AND of each of the light emitting elements ED may be disposed on the tenth interlayer insulating film INS10 and may be connected to the tenth via VA10. The first electrode AND of each of the light elements ED may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND of each of the light emitting elements ED may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND of each of the light emitting elements ED may be formed of titanium nitride (TiN).

The pixel defining film PDL may be disposed on the first electrode AND of each of the light emitting elements ED. The pixel defining film PDL may cover an edge of the first electrode AND and expose a center of the first electrode AND of each of the light emitting elements ED. The pixel defining film PDL serves to partition the first light emitting areas EA1, the second light emitting areas EA2, and the third light emitting areas EA3.

The first light emitting area EA1 may be defined as an area in which the first electrode AND, the intermediate layer IL, and the second electrode CAT are sequentially stacked in the first pixel PX1 to emit light. The second light emitting area EA2 may be defined as an area in which the first electrode AND, the intermediate layer IL, and the second electrode CAT are sequentially stacked in the second pixel PX2 to emit light. The third light emitting area EA3 may be defined as an area in which the first electrode AND, the intermediate layer IL, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements ED, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as a silicon oxide (SiOx)-based inorganic film, but the exemplary embodiment of the present specification is not limited thereto. Each of a thickness of the first pixel defining film PDL1, a thickness of the second pixel defining film PDL2, and a thickness of the third pixel defining film PDL3 may be approximately 500 Å.

Each of the plurality of trenches TRC may be formed through the first pixel defining film PDL1, the second pixel defining film PDL2, the third pixel defining film PDL3, and the tenth interlayer insulating film INS10.

At least one trench TRC may be disposed between the pixels PX1, PX2, and PX3 adjacent to each other. It is illustrated in FIG. 6 that two trenches TRC are disposed between the pixels PX1, PX2, and PX3 adjacent to each other, but the exemplary embodiment of the present specification is not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2, and IL3 emitting different light. For example, the intermediate layer may include a first intermediate layer IL1 emitting light of a first color, a second intermediate layer IL2 emitting light of a third color, and a third intermediate layer IL3 emitting light of a second color. The first intermediate layer IL1, the second intermediate layer IL2, and the third intermediate layer IL3 may be sequentially stacked.

The first intermediate layer IL1 may have a structure in which a first hole transporting layer, a first organic light emitting layer emitting light of a first color, and a first electron transporting layer are sequentially stacked. The second intermediate layer IL2 may have a structure in which a second hole transporting layer, a second organic light emitting layer emitting light of a third color, and a second electron transporting layer are sequentially stacked. The third intermediate layer IL3 may have a structure in which a third hole transporting layer, a third organic light emitting layer emitting light of a second color, and a third electron transporting layer are sequentially stacked.

A first charge generation layer for supplying holes to the second intermediate layer IL2 and supplying electrons to the first intermediate layer IL1 may be disposed between the first intermediate layer IL1 and the second intermediate layer IL2. A second charge generation layer for supplying holes to the third intermediate layer IL3 and supplying electrons to the second intermediate layer IL2 may be disposed between the second intermediate layer IL2 and the third intermediate layer IL3.

The first intermediate layer IL1 may be disposed on the first electrodes AND and the pixel defining film PDL, and may be disposed on a bottom surface of each of the trenches TRC. Due to the trench TRC, the first intermediate layer IL1 may be disconnected between the pixels PX1, PX2, and PX3 adjacent to each other. The second intermediate layer IL2 may be disposed on the first intermediate layer IL1. Due to the trench TRC, the second intermediate layer IL2 may be disconnected between the pixels PX1, PX2, and PX3 adjacent to each other. The third intermediate layer IL3 may be disposed on the second intermediate layer IL2. Due to the trench TRC, the third intermediate layer IL3 may be disconnected between the pixels PX1, PX2, and PX3 adjacent to each other. That is, each of the plurality of trenches TRC may be a structure for disconnecting the first to third intermediate layers IL1, IL2, and IL3 of the light emitting element layer EMTL between the pixels PX1, PX2, and PX3 adjacent to each other.

In order to stably disconnect the first to third intermediate layers IL1, IL2, and IL3 of the light emitting element layer EMTL between the pixels PX1, PX2, and PX3 adjacent to each other, a depth of each of the plurality of trenches TRC may be greater than that of the pixel defining film PDL. The depth of each of the plurality of trenches TRC indicates a length of each of the plurality of trenches TRC in the third direction DR3. The height of the pixel defining film PDL indicates a length of the pixel defining film PDL in the third direction DR3.

In order to disconnect the first to third intermediate layers IL1, IL2, and IL3 of the light emitting element layer EMTL between the pixels PX1, PX2, and PX3 adjacent to each other, other structures may be present instead of the trench TRC. For example, instead of the trench TRC, a partition wall having a reverse tapered shape may be disposed on the pixel defining film PDL.

The number of intermediate layers IL1, IL2, and IL3 emitting different lights is not limited to that illustrated in FIG. 6. For example, the intermediate layer IL may include two intermediate layers. In this case, one of the two intermediate layers may be substantially the same as the first intermediate layer IL1, and the other thereof may include a second hole transporting layer, a second organic light emitting layer, a third organic light emitting layer, and a second electron transporting layer. In this case, a charge generation layer for supplying electrons to one intermediate layer and supplying holes to the other intermediate layer may be disposed between the two intermediate layers.

In addition, it is illustrated in FIG. 6 that the first to third intermediate layers IL1, IL2, and IL3 are all disposed in the first light emitting area EA1, the second light emitting area EA2, and the third light emitting area EA3, but the exemplary embodiment of the present specification is not limited thereto. For example, the first intermediate layer IL1 may be disposed in the first light emitting area EA1 and may not be disposed in the second light emitting area EA2 and the third light emitting area EA3. In addition, the second intermediate layer IL2 may be disposed in the second light emitting area EA2 and may not be disposed in the first light emitting area EA1 and the third light emitting area EA3. In addition, the third intermediate layer IL3 may be disposed in the third light emitting area EA3 and may not be disposed in the first light emitting area EA1 and the second light emitting area EA2. In this case, first to third color filters CF1, CF2, and CF3 of the optical layer OPL may be omitted.

The second electrode CAT may be disposed on the third intermediate layer IL3. The second electrode CAT may be disposed on the third intermediate layer IL3 in each of the plurality of trenches TRC. The second electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). When the second electrode CAT is formed of a semi-transmissive conductive material, light emission efficiency may be increased in each of the first to third pixels PX1, PX2, and PX3 by micro cavities.

The encapsulation layer TFE may be disposed on the light emitting element layer EMTL. The encapsulation layer TFE may include one or more inorganic films TFE1 and TFE2 to prevent oxygen or moisture from permeating into the light emitting element layer EMTL. In addition, the encapsulation layer TFE may include at least one organic film to protect the light emitting element layer EMTL from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the second electrode CAT, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer (SiNx), a silicon oxynitride layer (SiON), a silicon oxide layer (SiOx), a titanium oxide layer (TiOx), and an aluminum oxide layer (AlOx) are alternately stacked. The encapsulation organic film TFE2 may be a monomer. In addition, the encapsulation organic film TFE2 may be an organic film made of an acrylic resin, an epoxy resin, a phenolic resin, a polyamide resin, or a polyimide resin.

An adhesive layer ADL may be a layer for adhering the encapsulation layer TFE and the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the adhesive layer ADL.

The first color filter CF1 may overlap the first light emitting area EA1 of the first pixel PX1. The first color filter CF1 may transmit light of a first color, that is, light in a blue wavelength band. The blue wavelength band may be approximately 370 nm to 460 nm. Therefore, the first color filter CF1 may transmit light of a first color among light emitted from the first light emitting area EA1.

The second color filter CF2 may overlap the second light emitting area EA2 of the second pixel PX2. The second color filter CF2 may transmit light of a second color, that is, light in a green wavelength band. The green wavelength band may be approximately 480 nm to 560 nm. Therefore, the second color filter CF2 may transmit light of a second color among light emitted from the second light emitting area EA2.

The third color filter CF3 may overlap the third light emitting area EA3 of the third pixel PX3. The third color filter CF3 may transmit light of a third color, that is, light in a red wavelength band. The red wavelength band may be approximately 600 nm to 750 nm. Therefore, the third color filter CF3 may transmit light of a third color among light emitted from the third light emitting area EA3.

Each of the plurality of lenses LNS may be disposed on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, or a polyimide resin.

The cover layer CVL may be disposed on the filling layer FIL. The cover layer CVL may be a glass substrate or a resin such as a polymer resin. When the cover layer CVL is a glass substrate, the cover layer CVL may be attached onto the filling layer FIL. In this case, the filling layer FIL may serve to adhere the cover layer CVL. When the cover layer CVL is a glass substrate, the cover layer CVL may serve as an encapsulation substrate. When the cover layer CVL is a resin such as a polymer resin, the cover layer CVL may be directly applied on the filling layer FIL.

The polarizing plate (not shown) may be disposed on one surface of the cover layer CVL. The polarizing plate may be a structure for preventing deterioration in visibility due to reflection of external light. The polarizing plate may include a linear polarizing plate and a phase retardation film. For example, the phase retardation film may be a λ/4 (quarter-wave) plate, but the exemplary embodiment of the present specification is not limited thereto. However, when deterioration in visibility due to reflection of external light is sufficiently improved by the first to third color filters CF1, CF2, and CF3, the polarizing plate may also be omitted.

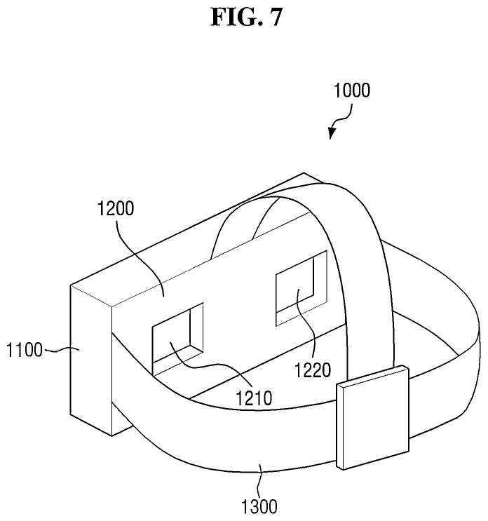

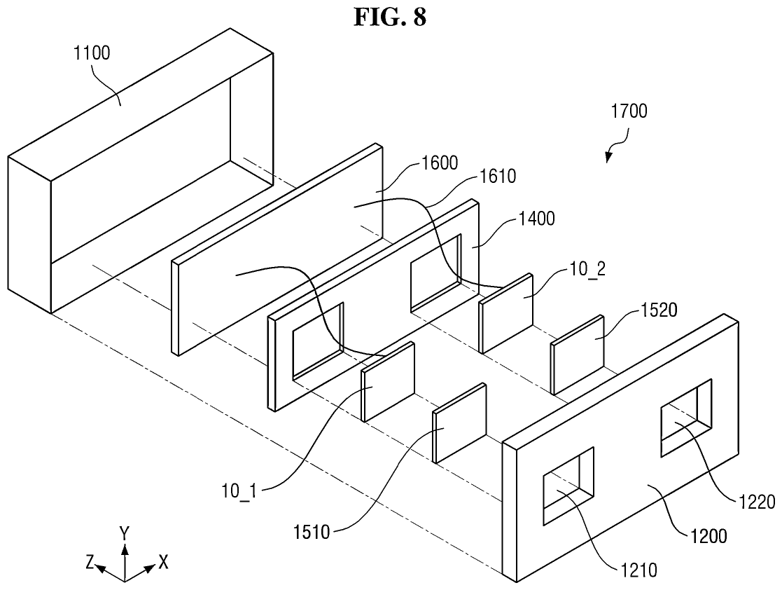

FIG. 7 is a perspective view illustrating a head mounted display device according to an exemplary embodiment. FIG. 8 is an exploded perspective view illustrating an example of a display unit 1700 of the head mounted display device of FIG. 7.

Referring to FIGS. 7 and 8, a head mounted display device 1000 as an optical device according to an exemplary embodiment includes a first display device 10_1, a second display device 10_2, a display device accommodating portion 1100, an accommodating portion cover 1200, optical path conversion members 1210, 1220, 1510, and 1520, a head mounting band 1300, a middle frame 1400, a control circuit board 1600, and a connector 1610.

The optical path conversion member may include a first eyepiece lens 1210, a second eyepiece lens 1220, a first optical member 1510, and a second optical member 1520.

The first display device 10_1 provides an image to the user's left eye, and the second display device 10_2 provides an image to the user's right eye. Since each of the first display device 10_1 and the second display device 10_2 is substantially the same as the display device 10 described with reference to FIGS. 1 to 6, descriptions of the first display device 10_1 and the second display device 10_2 are omitted.

The first optical member 1510 may be disposed between the first display device 10_1 and the first eyepiece lens 1210. The second optical member 1520 may be disposed between the second display device 10_2 and the second eyepiece lens 1220. Each of the first optical member 1510 and the second optical member 1520 may include at least one convex lens.

The middle frame 1400 may be disposed between the first display device 10_1 and the control circuit board 1600 and may be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device accommodating portion 1100. The control circuit board 1600 may be connected to the first display device 10_1 and the second display device 10_2 through a connector 1610. The control circuit board 1600 may convert an image source input from the outside into digital video data DATA, and may transmit the digital video data DATA to the first display device 10_1 and the second display device 10_2 through the connector 1610.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device accommodating portion 1100 serves to accommodate the first display device 10_1, the second display device 10_2, the middle frame 1400, the first optical member 1510, the second optical member 1520, the control circuit board 1600, and the connector 1610. The accommodating portion cover 1200 is disposed to cover one opened surface of the display device accommodating portion 1100. The accommodating portion cover 1200 may include a first eyepiece lens 1210 disposed in an area corresponding to the user's left eye and a second eyepiece lens 1220 disposed in an area corresponding to the user's right eye. It is illustrated in FIGS. 7 and 8 that the first eyepiece lens 1210 and the second eyepiece lens 1220 are separately disposed, but the exemplary embodiments of the present specification are not limited thereto. The first eyepiece lens 1210 and the second eyepiece lens 1220 may be integrated into one.

The first eyepiece lens 1210 may be aligned with the first display device 10_1 and the first optical member 1510, and the second eyepiece lens 1220 may be aligned with the second display device 10_2 and the second optical member 1520. Therefore, the user may view an image of the first display device 10_1 magnified as a virtual image by the first optical member 1510 through the first eyepiece lens 1210, and may view an image of the second display device 10_2 magnified as a virtual image by the second optical member 1520 through the second eyepiece lens 1220.

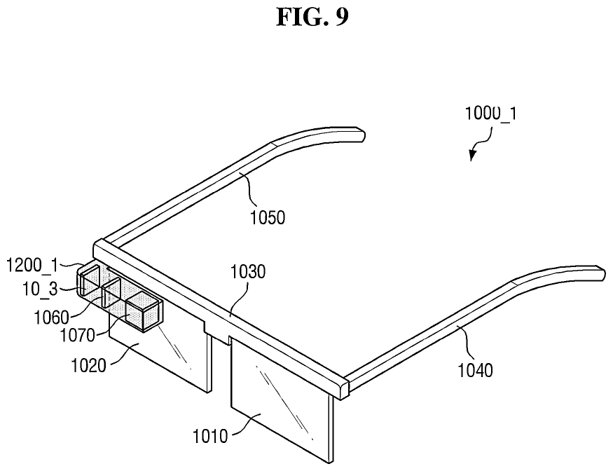

The head mounting band 1300 serves to fix the display unit 1700 to a user's head so that the first eyepiece lens 1210 and the second eyepiece lens 1220 of the accommodating portion cover 1200 are disposed on the user's left and right eyes, respectively. When the display device accommodating portion 1100 is implemented in a lightweight and small size, the head mounted display device 1000 may include eyeglass frames as illustrated in FIG. 9 instead of the head mounting band 1300.

In addition, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 9 is a perspective view illustrating a head mounted display device according to an exemplary embodiment.

Referring to FIG. 9, a head mounted display device 1000_1 according to an exemplary embodiment may be a glasses-type display device in which a display device accommodating portion 1200_1 is implemented in a lightweight and small size. The head mounted display device 1000_1 according to an exemplary embodiment may include a display device 10_3, a left eye lens 1010, a right eye lens 1020, a support frame 1030, eyeglass frame legs 1040 and 1050, an optical member 1060, an optical path conversion member 1070, and a display device accommodating portion 1200_1.

The display device accommodating portion 1200_1 may accommodate the display device 10_3, the optical member 1060, and the optical path conversion member 1070. As an image displayed on the display device 10_3 is magnified by the optical member 1060 and an optical path thereof is converted by the optical path conversion member 1070, the image may be provided to the user's right eye through the right eye lens 1020. Accordingly, the user may view an augmented reality image in which a virtual image displayed on the display device 10_3 and a real image seen through the right eye lens 1020 are combined through the right eye.

It is illustrated in FIG. 9 that the display device accommodating portion 1200_1 is disposed at a right distal end of the support frame 1030, but the exemplary embodiment of the present specification is not limited thereto. For example, the display device accommodating portion 1200_1 may be disposed at a left distal end of the support frame 1030, and in this case, the image of the display device 10_3 may be provided to the user's left eye. Alternatively, the display device accommodating portions 1200_1 may be disposed at both the left and right distal ends of the support frame 1030. In this case, the user may view the image displayed on the display device 10_3 through both the user's left and right eyes.

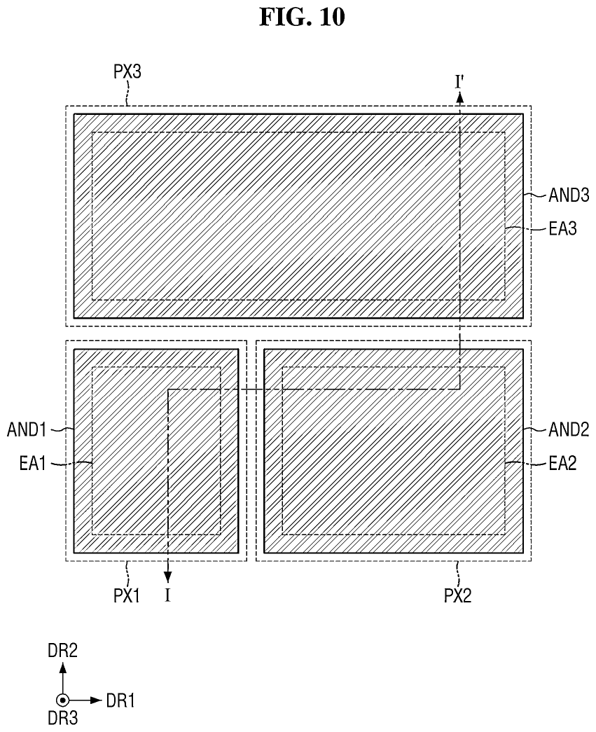

FIG. 10 is a plan view of a display device according to an exemplary embodiment.

As illustrated in FIG. 10, the display device 10 may include a first pixel PX1, a second pixel PX2, and a third pixel PX3. The first pixel PX1, the second pixel PX2, and the third pixel PX3 may form one unit pixel. In other words, a unit pixel may include a first pixel PX1, a second pixel PX2, and a third pixel PX3 disposed adjacent to each other.

The first to third pixels PX1 to PX3 of the unit pixel may be pixels providing light of different colors (or wavelengths). For example, the pixel PX1 may emit light of a first color, the second pixel PX2 may emit light of a second color, and the third pixel PX3 may emit light of a third color. Here, the first color may be any one of red, green, and blue, the second color may be another color different from the first color among red, green, and blue described above, and the third color may be the other color different from the first and second colors among red, green, and blue described above.

The first pixel PX1 may include a first pixel electrode AND1, the second pixel PX2 may include a second pixel electrode AND2, and the third pixel PX3 may include a third pixel electrode AND3.

The first pixel electrode AND1, the second pixel electrode AND2, and the third pixel electrode AND3 may be disposed adjacent to each other. For example, the first pixel electrode AND1 and the second pixel electrode AND2 may be disposed adjacent to each other in the first direction DR1, the second pixel electrode AND2 and the third pixel electrode AND3 may be disposed adjacent to each other in the second direction DR2, and the third pixel electrode AND3 and the first pixel electrode AND1 may be disposed adjacent to each other in the second direction DR2.

The first to third pixel electrodes AND1 to AND3 may have different sizes. For example, an area of the third pixel electrode AND1 may be greater than the sum of an area of the first pixel electrode AND1 and an area of the second pixel electrode AND2. In this case, the third pixel PX3 including the third pixel electrode AND3 may provide light of blue, the first pixel PX1 including the first pixel electrode AND1 may provide light of red, and the second pixel PX2 including the second pixel electrode AND2 may provide light of green. Meanwhile, as described above, when the third pixel PX3 provides light of blue, the first pixel PX1 provides light of red, and the second pixel PX2 provides light of green, the area of the second pixel electrode AND2 may be greater than that of the first pixel electrode AND1 and smaller than that of the third pixel electrode PE3.

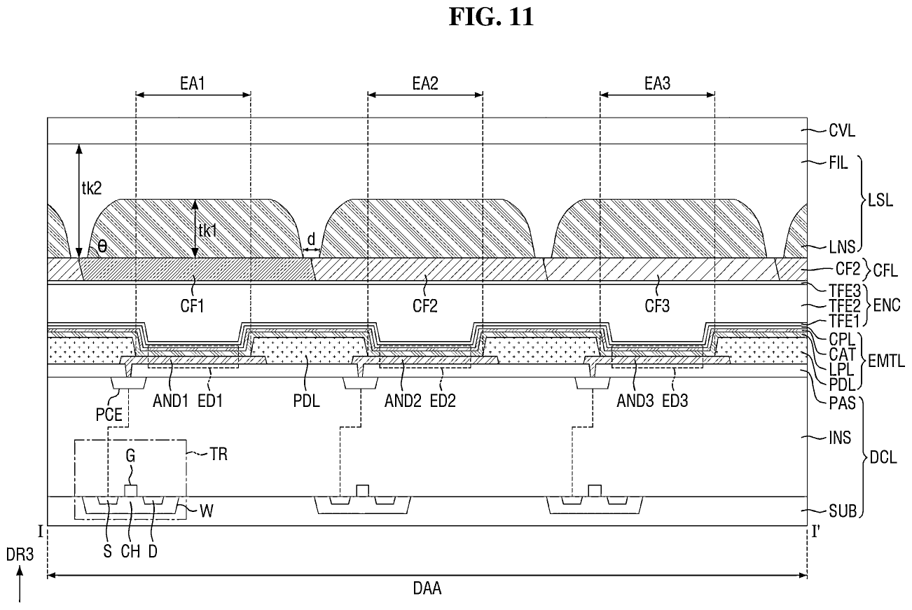

A portion of the first pixel electrode AND1 (e.g., an edge of the first pixel electrode AND1), a portion of the second pixel electrode AND2 (e.g., an edge of the second pixel electrode AND2), and a portion of the third pixel electrode AND3 (e.g., an edge of the third pixel electrode AND3) may be covered by a bank (a pixel defining film PDL in FIG. 11) to be described later. In other words, a portion of the first pixel electrode AND1 (e.g., an edge of the first pixel electrode AND1), a portion of the second pixel electrode AND2 (e.g., an edge of the second pixel electrode AND2), and a portion of the third pixel electrode AND3 (e.g., an edge of the third pixel electrode AND3) may partially overlap the bank PDL.

Exposed areas of the first pixel electrode AND1, the second pixel electrode AND2, and the third pixel electrode AND3 that are not covered by the bank PDL may be defined as a first light emitting area EA1, a second light emitting area EA2, and a third light emitting area EA3, respectively. For example, the first light emitting area EA1 may be a light emitting area of the first pixel PX1 including the first pixel electrode AND1, the second light emitting area EA2 may be a light emitting area of the second pixel PX2 including the second pixel electrode AND2, and the third light emitting area EA3 may be a light emitting area of the third pixel PX3 including the third pixel electrode AND3.

FIG. 11 is a cross-sectional view of the display device according to an exemplary embodiment taken along line I-I′ of FIG. 10.

As illustrated in FIG. 11, the display device 10 may include a driving circuit layer DCL, a light emitting element layer EMTL, an encapsulation layer ENC, a color filter layer CFL, a lens layer LNS, and a cover layer CVL.

The substrate SUB may be a silicon substrate SUB, a germanium substrate SUB, or a silicon-germanium substrate SUB. The substrate SUB may be a substrate SUB doped with first-type impurities.

A well W may be disposed in the substrate SUB. The well W may be an area doped with second-type impurities. The second-type impurity may be different from the first-type impurity described above. For example, when the first-type impurity is a p-type impurity, the second-type impurity may be an n-type impurity. Meanwhile, when the first-type impurity is an n-type impurity, the second-type impurity may be a p-type impurity.

A source area S, a drain area D, and a channel area CH of the transistor TR may be disposed in the well W. For example, a source area S (or source electrode) and a drain area D (or drain electrode D) of the transistor TR may be disposed in the well W. Each of the source area S and the drain area D may be an area doped with the first-type impurities described above. The gate electrode G of the transistor TR may intersect and overlap the well W. In a plan view, the well W intersected by the gate electrode G may be defined as two areas, and the source area S may be disposed in one of the two areas, and the drain area D may be disposed in the other area. In other words, in the well W, the source area S and the drain area D may be respectively disposed on both sides of the channel area CH with the channel area CH interposed therebetween. The channel area CH of the transistor may be disposed in an area of the well W overlapping the gate electrode G. The transistor TR illustrated in FIG. 11 may be, for example, the fourth transistor T4 of FIG. 4.

Meanwhile, the source area S may include a first lightly doped area having a relatively lower impurity concentration than other portions of the source area S. In other words, a portion of the source area S may include impurities at a lower concentration than other portions of the source area S. The drain area D may include a second lightly doped area having a relatively lower impurity concentration than other portions of the drain area D. In other words, a portion of the drain area D may include impurities at a lower concentration than other portions of the drain area D.

The first lightly doped area and the second lightly doped area may be disposed close to the channel area CH of the transistor TR. For example, the first lightly doped area may be disposed close to the channel area CH to overlap a first spacer (not shown) disposed on one side of the gate electrode G, and the second lightly doped area may be disposed close to the channel area CH to overlap a second spacer (not shown) disposed on the other side of the gate electrode G. In this way, a distance between the highly doped impurity area of the source area S and the highly doped impurity area of the drain area D may be increased by the first lightly doped area and the second lightly doped area, and as the distance increases, a length of the channel area CH may eventually increase. Accordingly, punch-through and hot carrier phenomena caused by a short channel may be prevented.

An interlayer insulating film INS may be disposed on the substrate SUB.

A passivation film PAS may be disposed on the interlayer insulating film INS.

A light emitting element layer EMTL may be disposed on the passivation film PAS. The light emitting element layer EMTL may include, for example, a first light emitting element ED1, a second light emitting element ED2, and a third light emitting element ED3 disposed in different light emitting areas. For example, the first light emitting element ED1 of the light emitting element layer EMTL may be disposed in the first light emitting area EA1, the second light emitting element ED2 of the light emitting element layer EMTL may be disposed in the second light emitting area EA2, and the third light emitting element ED3 of the light emitting element layer EMTL may be disposed in the third light emitting area EA3.

Each of the first light emitting element ED1, the second light emitting element ED2, and the third light emitting element ED3 may emit white light.

The first light emitting element ED1 may include a first pixel electrode PE1 (or a first anode electrode), a light providing layer LPL, and a common electrode CAT stacked in the third direction DR3. Here, the first pixel electrode AND1 may correspond to the first electrode AND disposed on the left side in FIG. 6.

The second light emitting element ED2 may include a second pixel electrode AND2 (or second anode electrode), a light providing layer LPL, and a common electrode CAT stacked in the third direction DR3. Here, the second pixel electrode AND2 may correspond to the first electrode AND disposed in the middle in FIG. 6.

The third light emitting element ED3 may include a third pixel electrode AND3 (or third anode electrode), a light providing layer LPL, and a common electrode CAT stacked in the third direction DR3. Here, the third pixel electrode AND3 may correspond to the first electrode AND disposed on the right side in FIG. 6.

Here, the light providing layer LPL and the common electrode CAT may be a common layer commonly used in each of the light emitting elements ED1 to ED3. In other words, the plurality of light emitting elements ED1 to ED3 of the light emitting element layer EMTL may share the light providing layer LPL and the common electrode CAT.

Since the light providing layer LPL may include a plurality of light emitting layers providing light of different colors, the plurality of light emitting layers may be stacked along the third direction DR3. White light may be generated by mixing light of different colors from the plurality of light emitting layers. Meanwhile, the light providing layer (LPL) may further include a charge generation layer.

The light providing layer LPL may correspond to the intermediate layer IL of FIG. 6 described above. In this case, the light providing layer LPL may have the same structure as the intermediate layer IL of FIG. 6.

Each of the first pixel electrode AND1, the second pixel electrode AND2, and the third pixel electrode AND3 may be connected to each source area S of each transistor TR through a pixel connection electrode PCE.

The first pixel electrode AND1 may be disposed to correspond to the first light emitting area EA1, the second pixel electrode AND2 may be disposed to correspond to the second light emitting area EA2, and the third pixel electrode AND3 may be disposed to correspond to the third light emitting area EA3.

A bank PDL (or pixel defining film) may be disposed on the first pixel electrode AND1, the second pixel electrode AND2, and the third pixel electrode AND3.

The bank PDL may define each light emitting area of each of the pixels PX1 to PX3 (e.g., the first light emitting area EA1 of the first pixel PX1, the second light emitting area EA2 of the second pixel PX2, and the third light emitting area EA3 of the third pixel PX3). To this end, the bank PDL may be disposed to expose a partial area of each of the first pixel electrode AND1, the second pixel electrode AND2, and the third pixel electrode AND3 on the passivation film PAS. The bank PDL may cover edges of the first pixel electrode AND1, the second pixel electrode AND2, and the third pixel electrode AND3. The bank PDL may be formed as an organic film made of an acryl resin, an epoxy resin, a phenolic resin, a polyamide resin, or a polyimide resin.

The light providing layer LPL may be disposed on each of the pixel electrodes AND1, AND2, and AND3 and the bank PDL. For example, the light providing layer LPL may be disposed on the first pixel electrode AND1, the second pixel electrode AND2, the third pixel electrode AND3, and the bank PDL.

The bank PDL may correspond to the pixel defining film PDL of FIG. 6 described above. The bank PDL may have the same structure as the pixel defining film PDL of FIG. 6.

The light providing layer LPL may include a plurality of light emitting units. For example, the light providing layer LPL may include a first light emitting unit, a second light emitting unit, and a third light emitting unit stacked in the third direction DR3. The respective light emitting units may provide light of different wavelengths. For example, the first light emitting unit, the second light emitting unit, and the third light emitting unit may emit light of different colors. For example, the light providing layer LPL may have a tandem structure in which a plurality of light emitting units providing light of different colors are stacked in a vertical direction (e.g., in the third direction DR3).

The first light emitting unit may be disposed on each of the pixel electrodes AND1, AND2, and AND3. The first light emitting unit may include a first light emitting layer, a hole transporting layer, an organic material layer, and an electron transporting layer.

The second light emitting unit may be disposed on the first light emitting unit. The second light emitting unit may include a second light emitting layer, a hole transporting layer, an organic material layer, and an electron transporting layer.

The third light emitting unit may be disposed on the second light emitting unit. The third light emitting unit may include a third light emitting layer, a hole transporting layer, an organic material layer, and an electron transporting layer.

Each of the light emitting elements ED1, ED2, and ED3 may provide white light by mixing light of a first color (e.g., blue) from the first light emitting unit, light of a second color (e.g., red) from the second light emitting unit, and light of a third color (e.g., green) from the third light emitting unit. For example, each of the first light emitting element ED1, the second light emitting element ED2, and the third light emitting element ED3 may emit white light.

In addition, the light providing layer LPL may further include at least one charge generation layer in addition to the light emitting unit described above. The charge generation layer may be disposed between the light emitting units adjacent to each other in the third direction DR3, for example. The charge generation layer may include, for example, a first charge generation layer and a second charge generation layer stacked in the third direction DR3. In this case, the first charge generation layer may be disposed between the first light emitting unit and the second light emitting unit, and the second charge generation layer may be disposed between the second light emitting unit and the third light emitting unit.

Meanwhile, each charge generating layer may include a negative charge generating layer and a positive charge generating layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

A common electrode CAT may be disposed on the light providing layer LPL. For example, the common electrode CAT may be disposed on the light providing layer LPL to overlap the first pixel electrode AND1, the second pixel electrode AND2, the third pixel electrode AND3, the first light emitting area EA1, the second light emitting area EA2, the third light emitting area EA3, and the bank PDL. In a top emission structure, the common electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). When the common electrode CAT is formed of the semi-transmissive conductive material, light emission efficiency may be increased by a micro cavity. The common electrode CAT may correspond to the second electrode CAT of FIG. 6 described above. The common electrode CAT may have the same structure as the second electrode CAT of FIG. 6.

A capping layer CPL may be disposed on the common electrode CAT. The capping layer CPL may include an inorganic insulating material. In an exemplary embodiment, the capping layer CPL may include aluminum oxide, titanium oxide, tantalum oxide, hafnium oxide, zinc oxide, silicon oxide, silicon nitride, and/or silicon oxynitride.

An encapsulation layer ENC may be disposed on the capping layer CPL. The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL. The encapsulation layer ENC may include one or more inorganic films TFE1 and TFE3 to prevent oxygen or moisture from permeating into the light emitting element layer EMTL. In addition, the encapsulation layer TFE may include at least one organic film to protect the light emitting element layer EMTL from foreign substances such as dust. For example, the encapsulation layer TFE may include a first encapsulation inorganic film TFE1, an encapsulation organic film TFE2, and a second encapsulation inorganic film TFE3.

The first encapsulation inorganic film TFE1 may be disposed on the capping layer CPL, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, or a polyimide resin.

In addition, the display device 10 may include a plurality of color filters CF1, CF2, and CF3 disposed on the light emitting areas EA1, EA2, and EA3. Each of the plurality of color filters CF1, CF2, and CF3 may be disposed to correspond to the light emitting areas EA1, EA2, and EA3. For example, the color filters CF1, CF2, and CF3 may be disposed on the encapsulation layer ENC to correspond to the light emitting areas EA1, EA2, and EA3.

The color filters CF1, CF2, and CF3 may include a first color filter CF1, a second color filter CF2, and a third color filter CF3 disposed to correspond to different light emitting areas EA1, EA2, and EA3, respectively. The color filters CF1, CF2, and CF3 may include a colorant such as a dye or pigment that absorbs light in a wavelength band other than light in a specific wavelength band, and may be disposed to correspond to the colors of light emitted from the light emitting areas EA1, EA2, and EA3. For example, the first color filter CF1 may be a red color filter that is disposed to overlap the first light emitting area EA1 and transmits only first light of red. The second color filter CF2 may be a green color filter that is disposed to overlap the second light emitting area EA2 and transmits only second light of green, and the third color filter CF3 may be a blue color filter that is disposed to overlap the third light emitting area EA3 and transmits only third light of blue.

The plurality of color filters CF1, CF2, and CF3 may be disposed to partially overlap other adjacent color filters CF1, CF2, and CF3. Meanwhile, in an overlapping area between the color filters, a thickness of an overlapping portion of the adjacent color filters may be, for example, 1.5 μm. Here, the thickness of the overlapping portion of the adjacent color filters may be a length in the third direction DR3. In addition, in an overlapping area between the adjacent color filters, a width of an overlapping portion of the adjacent color filters may be, for example, less than or equal to 0.2 μm. Here, the width of the overlapping portion of the adjacent color filters may be a size in the first direction DR1 or the second direction DR2. The different color filters CF1, CF2, and CF3 are areas that do not overlap the light emitting areas EA1, EA2, and EA3, and may overlap each other in area corresponding to the bank PDL. In the display device 10, as the color filters CF1, CF2, and CF3 are disposed to overlap each other, intensity of reflected light caused by external light may be reduced. Furthermore, the color of reflected light caused by external light may also be controlled by adjusting the arrangement, shape, and area of the color filters CF1, CF2, and CF3 in a plan view.

Meanwhile, although not illustrated, the display device 10 according to an exemplary embodiment may further include a light blocking layer disposed between adjacent color filters (e.g., between CF1 and CF2 or between CF2 and CF3) on the encapsulation layer ENC. The light blocking layer may include a plurality of holes disposed in areas corresponding to each of the light emitting areas EA1, EA2, and EA3. For example, a first hole of the light blocking layer may be disposed in an area corresponding to the first light emitting area EA1, a second hole of the light blocking layer may be disposed in an area corresponding to the second light emitting area EA2, and a third hole of the light blocking layer may be disposed in an area corresponding to the third light emitting area EA3. Areas or sizes of the holes of the light blocking layer may be greater than those of the light emitting areas EA1, EA2, and EA3 defined by the bank PDL. As the holes of the light blocking layer are formed to be greater than the light emitting areas EA1, EA2, and EA3, light emitted from the light emitting areas EA1, EA2, and EA3 may be visually recognized by a user not only from a front side of the display device 10 but also from a side surface thereof.

In an exemplary embodiment, each of the color filters CF1, CF2, and CF3 covers the holes of the light blocking layer and has an area greater than that of the hole, and may have an area that is spaced apart from the other color filters CF1, CF2, and CF3 on the light blocking layer. The plurality of color filters CF1, CF2, and CF3 may be spaced apart from other adjacent color filters CF1, CF2, and CF3 on the light blocking layer BM.

The lens layer LSL may be disposed on the color filter layer CFL. The lens layer LSL may be in direct contact with (or be in contact with, or be directly connected to) the color filter layer CFL on the color filter layer CFL. For example, the lens layer LSL may be in direct contact with the plurality of color filters CF1, CF2, and CF3. The lens layer LSL may include a plurality of lenses LNS (e.g., a plurality of micro lenses) and a filling layer FIL.

Each of the plurality of lenses LNS may be disposed on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction (e.g., a light emitting direction or the third direction). A distance d (e.g., a shortest distance) between adjacent lenses LNS may be greater than or equal to 0.3 μm, for example. Here, the distance d between adjacent lenses LNS may be a size in the first direction DR1 or the second direction DR2. In addition, a thickness tk1 (e.g., a maximum thickness) of the lens LNS may be smaller than, for example, 1.5 μm. Here, the thickness tk1 of the lens LNS may be a length of the lens LNS in the third direction DR3. In addition, a taper angle θ of the lens LNS may be 60 degrees to 70 degrees. Here, the taper angle θ of the lens LNS may refer to an angle formed between a tangent line of an edge of the lens LNS and a lower surface of the lens LNS (e.g., an interface between the lens LNS and the color filter layer CFL). In addition, the lens LNS may have, for example, a refractive index of 1.61. Meanwhile, the thickness tk1 of the lens LNS may be the same as the thickness of the overlapping portion of adjacent color filters described above. For example, when the thickness of the lens LNS is 1.5 μm, the thickness of the overlapping portion of adjacent color filters (e.g., CF1 and CF2) may also be 1.5 μm.

The filling layer FIL may be disposed on the plurality of lenses LNS. The filling layer FIL may have a predetermined refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, or a polyimide resin. The filling layer FIL may have a smaller refractive index than the lens LNS described above. In this case, a difference between the refractive index of the filling layer FIL and the refractive index of the lens LNS may be, for example, 0.1 to 0.2. For example, the filling layer FIL may have a refractive index of 1.41 to 1.51. In an exemplary embodiment, the refractive index of the lens LNS described above may be 1.61, and the refractive index of the filling layer FIL may be 1.51. In an exemplary embodiment, the filling layer FIL may have a thickness tk2 of 3 μm.

The cover layer CVL may be disposed on the filling layer FIL. The cover layer CVL may be a glass substrate or a polymer resin such as resin. When the cover layer CVL is a glass substrate, the cover layer CVL may be attached onto the filling layer FIL. In this case, the filling layer FIL may serve to adhere the cover layer CVL. When the cover layer CVL is a glass substrate, the cover layer CVL may serve as an encapsulation substrate. When the cover layer CVL is a polymer resin such as resin, the cover layer CVL may be directly applied on the filling layer FIL.

As described above, when the refractive index of the lens LNS is 1.61 and the refractive index of the filling layer FIL is 1.51, a condition that a color gamut of the display device 10 may be improved and the thickness tk2 of the filling layer FIL may be minimized may be satisfied. In other words, when the refractive index of the lens LNS and the refractive index of the filling layer FIL are satisfied, the color gamut of the display device 10 may be improved even if the thickness tk2 of the filling layer FIL is thick. Therefore, the filling layer FIL may be formed to have enough thickness not to cause an unfilling defect of a filling material, and a decrease in the color gamut of the display device 10 may be prevented. Here, the thickness tk2 (e.g., maximum thickness) of the filling layer FIL may refer to a length of the filling layer FIL in the third direction DR3.

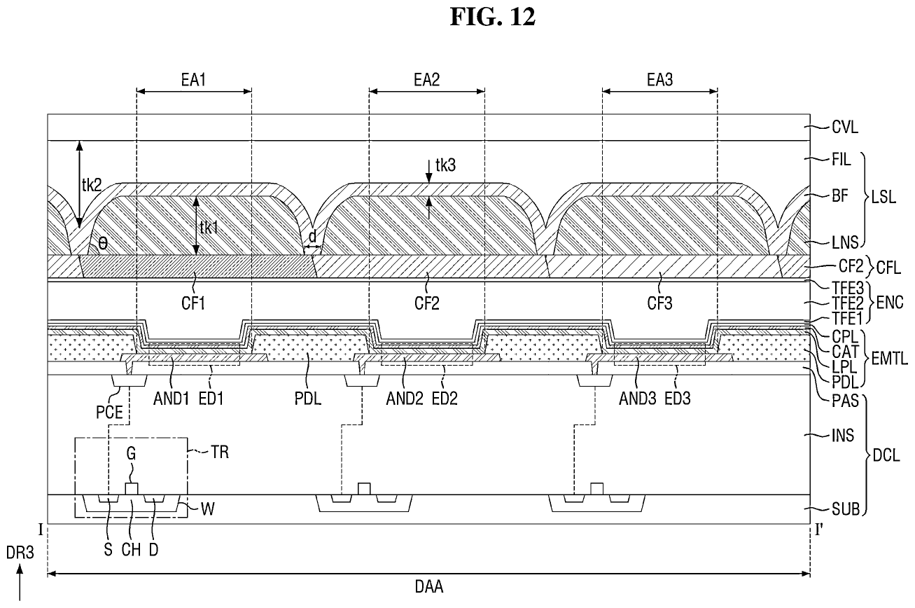

FIG. 12 is a cross-sectional view of the display device according to an exemplary embodiment taken along line I-I′ of FIG. 10.

The display device 10 of FIG. 12 is different from the display device 10 of FIG. 11 in that the display device 10 of FIG. 12 further includes a buffer layer BF, and such a difference will be mainly described as follows.

As illustrated in FIG. 12, the lens layer LSL may further include a buffer layer BF.

The buffer layer BF may be disposed between the plurality of lenses LNS and the filling layer FIL. In addition, the buffer layer BF may be disposed between adjacent lenses LNS. For example, the lens layer LSL may further include a buffer layer BF disposed between the plurality of lenses LNS and the filling layer FIL and between adjacent lenses LNS.

The buffer layer BF may have a high surface energy so that spreadability of the filling layer FIL disposed thereon may be improved. For example, the buffer layer BF may have a surface energy of 60 mN/m or more. The spreadability of the filling layer FIL may be improved by the buffer layer BF having such a high surface energy, and accordingly, while the thickness tk2 of the filling layer FIL is maintained to be low, film density of the filling layer FIL may be improved. Therefore, even if the thickness tk2 of the filling layer FIL is low, the unfilling defect of the filling material of the filling layer FIL may be prevented. Furthermore, since the thickness tk2 of the filling layer FIL is reduced, the color gamut of the display device 10 may also be improved. Here, the thickness tk2 of the filling layer FIL may refer to a length of the filling layer FIL in the third direction DR3.

The buffer layer BF may have a refractive index of 1.4 to 1.7. For example, the buffer layer BF may have a refractive index of 1.4 to 1.7 at a wavelength of 550 nm.

The buffer layer BF may have a thickness tk3 smaller than 1000 Å. When the buffer layer BF has a thickness tk3 smaller than 1000 Å, the buffer layer BF having the thickness tk3 may have a light transmittance of 85%. Here, the thickness tk3 of the buffer layer BF may refer to a length of the buffer layer BF in the third direction DR3.

The buffer layer BF may include, for example, SiOx, SiNy, or SiOxNy. Here, x may be greater than or equal to 0 and less than or equal to 1. In addition, y may be greater than or equal to 0 and less than or equal to 1.

The buffer layer BF may be formed using a plasma enhanced chemical vapor deposition (CVD) method. In this case, a temperature during the process of forming the buffer layer BF may be 70° C. to 300° C.

When the refractive index of the lens LNS is 1.61, the refractive index of the filling layer FIL is 1.51, and the refractive index of the buffer layer BF is 1.4 to 1.7, a condition that the color gamut of the display device 10 may be further improved and the thickness tk2 of the filling layer FIL may be minimized may be satisfied.

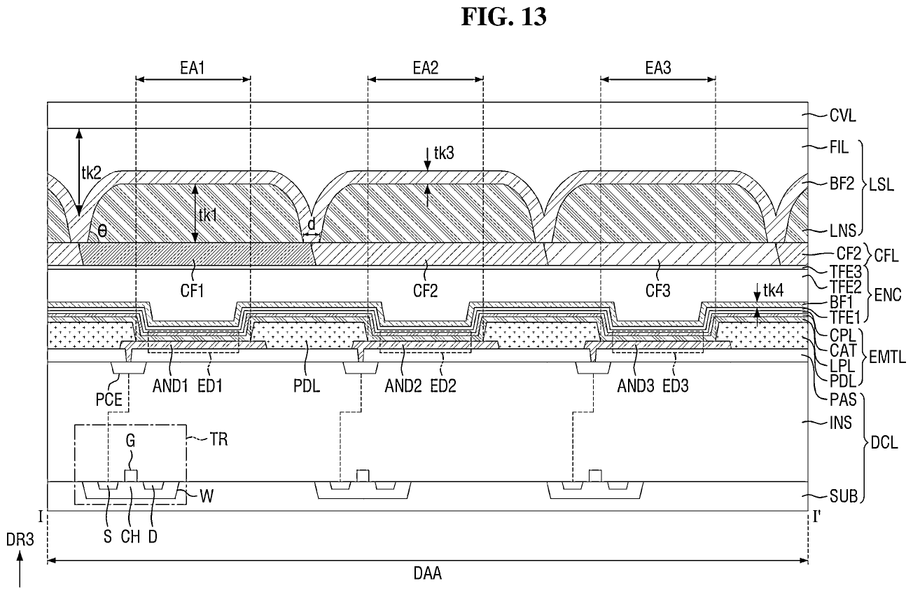

FIG. 13 is a cross-sectional view of the display device according to an exemplary embodiment taken along line I-I′ of FIG. 10.

The display device 10 of FIG. 13 is different from the display device 10 of FIG. 7 in that the display device 10 of FIG. 13 further includes a first buffer layer BF1 and a second buffer layer BF2, and such a difference will be mainly described as follows.

The first buffer layer BF1 may be disposed between the first encapsulation inorganic film TFE1 and the encapsulation organic film TFE2. For example, the encapsulation layer ENC may further include the first buffer layer BF1 disposed between the first encapsulation inorganic film TFE1 and the encapsulation organic film TFE2.

The first buffer layer BF1 may have a high surface energy so that spreadability of the encapsulation organic film TFE2 disposed thereon may be improved. For example, the first buffer layer BF1 may have a surface energy of 60 mN/m or more. The spreadability of the encapsulation organic film TFE2 may be improved by the first buffer layer BF1 having such a high surface energy, and accordingly, while the thickness of the encapsulation organic film TFE2 is maintained to be low, film density of the encapsulation organic film TFE2 may be improved. The first buffer layer BF1 may have a thickness tk4 smaller than 1000 Å.

Since the second buffer layer BF2 is the same as the buffer layer BF of FIG. 12 described above, the description of the second buffer layer BF2 is omitted for brevity.

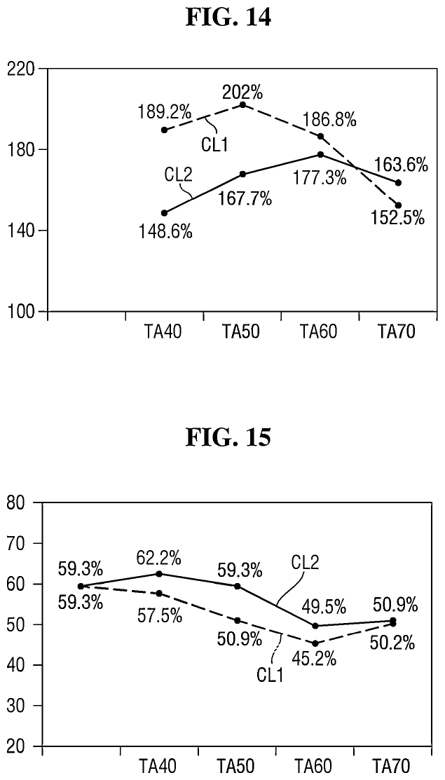

FIG. 14 is a view for describing front light efficiency of a display device according to a refractive index of a filling layer FIL and a taper angle θ of a lens LNS.

In FIG. 14, an X axis means a taper angle θ of the lens LNS, and a Y axis means front efficiency of the display device.

In FIG. 14, a first curve CL1 represents front light efficiency of a first display device according to a taper angle θ of the lens LNS in the first display device to which the filling layer FIL having a refractive index of 1.41 is applied, and a second curve CL2 represents front light efficiency of a second display device according to a taper angle θ of the lens LNS in the second display device to which the filling layer FIL having a refractive index of 1.51 is applied.

The front light efficiency of the display device in FIG. 14 means, for example, front light efficiency of the display device for green light.

As illustrated in FIG. 14, when the taper angle θ of the lens LNS is about 40 degrees to about 60 degrees, it may be seen that the front efficiency of the first display device is superior to that of the second display device. On the other hand, when the taper angle θ of the lens LNS is about 70 degrees, it may be seen that the front efficiency of the second display device is superior to that of the first display device.

FIG. 15 is a view for describing side light efficiency (or side luminance ratio) of a display device according to a refractive index of a filling layer FIL and a taper angle θ of a lens LNS.

In FIG. 15, an X axis means a taper angle θ of the lens, and a Y axis means front efficiency of the display device.

In FIG. 15, a first curve CL1 represents side light efficiency (or side luminance ratio) of a first display device according to a taper angle θ of the lens LNS in the first display device to which the filling layer FIL having a refractive index of 1.41 is applied, and a second curve CL2 represents side light efficiency (or side luminance ratio) of a second display device according to a taper angle θ of the lens LNS in the second display device to which the filling layer FIL having a refractive index of 1.51 is applied. Here, an angle of the side surface may be defined by an angle formed between a vertical line passing through a center of a screen of the display device and an oblique line passing through the center of the screen of the display device to form a specific angle with the vertical line passing through a center of a screen of the display device. For example, the angle formed by the center vertical line and the oblique line may be 35 degrees.

The side light efficiency of the display device in FIG. 15 means, for example, side light efficiency of the display device for green light.

As illustrated in FIG. 15, when the taper angle θ of the lens LNS is about 40 degrees to about 60 degrees, it may be seen that the side efficiency of the second display device is superior to that of the first display device. On the other hand, when the taper angle θ of the lens LNS is about 70 degrees, it may be seen that the front efficiency of the first display device is substantially same to that of the second display device.

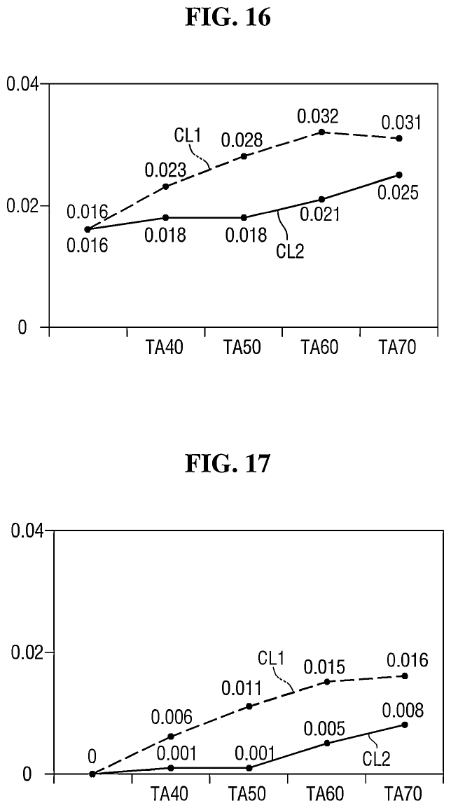

FIG. 16 is a view for describing a front color difference of a display device according to a refractive index of a filling layer FIL and a taper angle θ of a lens LNS.

In FIG. 16, an X axis means a taper angle θ of the lens LNS, and a Y axis means a front color difference of the display device.

In FIG. 16, a first curve CL1 represents a front color difference of a first display device according to a taper angle θ of the lens LNS in the first display device to which the filling layer FIL having a refractive index of 1.41 is applied, and a second curve CL2 represents a front color difference of a second display device according to a taper angle θ of the lens LNS in the second display device to which the filling layer FIL having a refractive index of 1.51 is applied.

The front color difference of the display device in FIG. 16 means, for example, a front color difference of the display device for green light.

As illustrated in FIG. 16, it may be seen that the front color difference of the second display device is lower than the front color difference of the first display device, regardless of the taper angle θ of the lens LNS. In other words, it may be seen that a color gamut of the second display device is superior to that of the first display device.

FIG. 17 is a view for describing a side color difference of a display device according to a refractive index of a filling layer FIL and a taper angle θ of a lens LNS.

In FIG. 17, an X axis means a taper angle θ of the lens LNS, and a Y axis means a side color difference of the display device.

In FIG. 17, a first curve CL1 represents a side color difference of a first display device according to a taper angle θ of the lens LNS in the first display device to which the filling layer FIL having a refractive index of 1.41 is applied, and a second curve CL2 represents a side color difference of a second display device according to a taper angle θ of the lens LNS in the second display device to which the filling layer FIL having a refractive index of 1.51 is applied. Here, an angle of the side surface may be defined by an angle formed between a vertical line passing through a center of a screen of the display device and a virtual line passing through the center of the screen to form a specific angle with the vertical line. For example, the angle formed by the center vertical line and the oblique line may be 35 degrees.

The side color difference of the display device in FIG. 17 means, for example, a side color difference of the display device for green light.

As illustrated in FIG. 17, it may be seen that the side color difference of the second display device is lower than the side color difference of the first display device, regardless of the taper angle θ of the lens LNS. In other words, it may be seen that a color gamut of the second display device is superior to that of the first display device.

Although some example embodiments of the present disclosure have been described above, these are merely examples and do not limit the present disclosure. Further, the present disclosure may be changed and modified in various ways, without departing from the features of the present disclosure, by those skilled in the art. For example, the components described in the example embodiments of the present disclosure may be modified. Differences related to these modifications and applications should be construed as being within the scope of the present disclosure defined by the claims.

What is claimed is:

1. A display device comprising:
a substrate;
a transistor disposed on the substrate;
a pixel electrode connected to the transistor;
a light emitting layer disposed on the pixel electrode;
a common electrode disposed on the light emitting layer;
a first color filter disposed on the common electrode;
a lens disposed on the color filer; and
a filling layer disposed on the lens,
wherein the first color filter and the lens are in direct contact with each other.

2. The display device of claim 1, wherein a difference between a refractive index of the lens and a refractive index of the filling layer is 0.1 to 0.2.

3. The display device of claim 1, wherein a refractive index of the lens is greater than a refractive index of the filling layer.

4. The display device of claim 1, wherein the lens has a refractive index of 1.61.

5. The display device of claim 1, wherein the lens has a taper angle of 60 degrees to 70 degrees.

6. The display device of claim 1, wherein the lens has a thickness smaller than 1.5 μm.

7. The display device of claim 1, wherein a distance between adjacent lenses is greater than or equal to 0.3 μm.

8. The display device of claim 1, wherein the filling layer has a refractive index of 1.41 to 1.51.

9. The display device of claim 1, wherein the filling layer includes an epoxy.

10. The display device of claim 1, wherein the filling layer has a thickness of 3 μm.

11. The display device of claim 1, further comprising a second buffer layer disposed between the lens and the filling layer.

12. The display device of claim 11, wherein the second buffer layer has a refractive index of 1.4 to 1.7.

13. The display device of claim 11, wherein the second buffer layer has a thickness smaller than 1000 Å.

14. The display device of claim 11, wherein the second buffer layer has a surface energy greater than or equal to 60 mN/m.

15. The display device of claim 11, wherein the second buffer layer includes SiOxNy.

16. The display device of claim 1, further comprising an encapsulating layer disposed between the common electrode and the first color filter.

17. The display device of claim 16, wherein the encapsulation layer includes at least one inorganic film and at least one organic film disposed on different layers.

18. The display device of claim 17, wherein the encapsulation layer further includes a first buffer layer disposed between the inorganic film and the organic film of the encapsulation layer.

19. The display device of claim 18, wherein the first buffer layer has a refractive index of 1.4 to 1.7.

20. The display device of claim 1, further comprising a second color filter disposed adjacent to the first color filter and overlapping the first color filter in a plan view.

21. The display device of claim 20, wherein a thickness of an overlapping portion of the first color filter and the second color filter is equal to a thickness of the lens.

22. The display device of claim 20, wherein a width of an overlapping portion of the first color filter and the second color filter is less than or equal to 0.2 μm.

23. A display device comprising:
a substrate;
a transistor disposed on the substrate;
a pixel electrode connected to the transistor;
a light emitting layer disposed on the pixel electrode;
a common electrode disposed on the light emitting layer;
a color filter disposed on the common electrode;
a lens disposed on the color filer; and
a filling layer disposed on the lens,
wherein the filling layer has a refractive index of 1.41 to 1.51.

24. The display device of claim 23, wherein a difference between a refractive index of the lens and the refractive index of the filling layer is 0.1 to 0.2.

25. The display device of claim 23, wherein a refractive index of the lens is greater than the refractive index of the filling layer.

26. The display device of claim 23, wherein the lens has a refractive index of 1.61.

27. The display device of claim 23, wherein the lens has a taper angle of 60 degrees to 70 degrees.

28. The display device of claim 23, wherein the color filter and the lens are in direct contact with each other.

29. An optical device comprising:
a display device; and
an optical path conversion member disposed on the display device,
wherein the display device includes:
a substrate;
a transistor disposed on the substrate;
a pixel electrode connected to the transistor;
a light emitting layer disposed on the pixel electrode;
a common electrode disposed on the light emitting layer;
a color filter disposed on the common electrode;
a lens disposed on the color filer; and
a filling layer disposed on the lens, and
wherein the color filter and the lens are in direct contact with each other.
